(19) United States
(12) Patent Application Publication
(10) Pub. No.: US 2014/0084137 A1
(43) Pub. Date: Mar. 27, 2014

(54) SWITCHABLE SUBSTRATES FOR PHOTOGRAPHY AND VIDEO ENHANCEMENT APPLICATIONS

(71) Applicants: Wilhelmus A. de Groot, Palo Alto, CA (US); Nicholas I. Buchan, San Jose, CA (US); Fan Yang, Sunnyvale, CA (US); Philip D. Floyd, Redwood City, CA (US); Russel A. Martin, Menlo Park, CA (US)

(72) Inventors: Wilhelmus A. de Groot, Palo Alto, CA (US); Nicholas I. Buchan, San Jose, CA (US); Fan Yang, Sunnyvale, CA (US); Philip D. Floyd, Redwood City, CA (US); Russel A. Martin, Menlo Park, CA (US)

(21) Appl. No.: 13/629,189

(22) Filed: Sep. 27, 2012

(51) Int. Cl. H01L 27/146

(52) U.S. Cl. CPC H01L 27/14625; H01L 27/14685
USPC 250/208.1; 438/59

(57) ABSTRACT

This disclosure provides systems, methods and apparatus relating to implementations of a switchable substrate that can be used in an imaging device. In one aspect, the switchable substrate includes a plurality of pixels, with each pixel having at least one switchable element. The switchable element can be switched between a first optical state and a second optical state. In the first optical state, a first spectral band of broadband light is reflected from the switchable element while a second spectral band is transmitted through the switchable element. In the second optical state, the first spectral band of the broadband light is transmitted through the switchable element while the second spectral band is reflected from the switchable element.

### TECHNICAL FIELD

This disclosure relates to the field of elements that can be switched between a reflective state and a transmissive state and their application in still and motion photography.

### DESCRIPTION OF THE RELATED TECHNOLOGY

The quality of images obtained by still and video cameras can be enhanced by capturing all the available information of the scene being captured. For example, the color quality and resolution of images captured by photography and video equipment can be enhanced by obtaining images in the visible spectral range as well as the infrared spectral range. Some photography and video equipment capture both the visible spectral image and the infrared spectral image simultaneously by using two side-by-side sensors. One of the side-by-side sensors is a sensor that is sensitive to visible spectral range and the other is a sensor that is sensitive to an infrared spectral range (e.g., the near infrared spectral range including wavelengths in the range from approximately 750 nm-3000 nm). The visible and infrared spectral images can be computationally combined to provide an enhanced image.

Present day photography and video equipment can include a number of mechanical parts. For example, Digital Single-Lens Reflex (DSLR) cameras can include a reflex mirror that is arranged at an angle with respect to an optical path extending from the objects being photographed and the sensor. The reflex mirror is configured to reflect light from the objects towards a view finder so that the photographer can compose the scene, focus on the objects to be photographed and adjust parameters such as the aperture, exposure time, etc. When the photographer is ready to take the photograph, the reflex mirror is mechanically moved out of the optical path such that the light from the objects is incident on the sensor.

### SUMMARY

The systems, methods and devices of the disclosure each have several innovative aspects, no single one of which is solely responsible for the desirable attributes disclosed herein.

One innovative aspect of the subject matter described in this disclosure can be implemented in an imaging device comprising a sensor configured to detect light in visible and infrared spectral ranges propagating along an optical path from a light source of ambient light and a switchable substrate having a forward surface that receives light from the source and a rearward surface opposite the forward surface. In various implementations, the sensor can include a photodiode including at least one of: silicon, germanium and gallium arsenide (GaAs). The switchable substrate is disposed on the optical path between the source of light and the sensor. The switchable substrate is disposed on the optical path such that a normal to the forward surface is oriented at a non-zero angle with respect to the optical path. In various implementations, the non-zero angle can be about 30 degrees, 45 degrees, 60 degrees or 75 degrees.

The switchable substrate includes a plurality of pixels. Each pixel includes at least one switchable element that is capable of being switched between a first optical state and a second optical state. In the first optical state, a first spectral band of the broadband light is reflected from the switchable element toward a viewing system offset from the optical path. In various implementations, the viewing system can include a display. In the second optical state, the first spectral band is transmitted through the switchable element toward the sensor. In various implementations, the switchable substrate can be switched between the first state and the second state in less than about 100 microseconds. In various implementations, when the switchable element is in the first state, a second spectral band of the broadband light is transmitted through the switchable element toward the sensor. In various implementations, the first spectral band can include a portion of the visible spectrum. For example, in various implementations, the first spectral band can include wavelengths in a range between approximately 380 nm and 750 nm. In various implementations, the second spectral band can include a portion of the near infrared spectrum. For example, in various implementations, the second spectral band can include wavelengths in a range between approximately 750 nm and 3000 nm. In various implementations, in the first optical state, the first spectral band can be reflected with a reflectivity between approximately 60% and approximately 99%. In various implementations, in the second optical state, the first spectral band can be transmitted with a transmissivity between approximately 60% and approximately 99%.

In various implementations, the switchable element can include an optical stack and a movable layer that is separated from the optical stack by a gap having a height. The movable layer is configured to be moved to change the height of the gap and to switch the switchable element between the first state and the second state. The optical stack can include a transparent conducting oxide. The movable layer can include a transparent conducting oxide. In various implementations, each pixel is individually addressable to create spatial patterns in the reflected or transmitted broadband light. In various implementations, the at least one switchable element included in each pixel can be temporally modulated for an exposure time.

In various implementations, the at least one switchable element included in each pixel can be temporally modulated by using at least one of: time modulated signal, frequency modulated signal and pulse width modulated signal. Various implementations of the imaging device described herein can be configured as a camera (for example, still or motion camera).

Another innovative aspect of the subject matter described in this disclosure can be implemented in an imaging device comprising means for detecting light in visible and infrared spectral ranges propagating along an optical path from a source of light and a switchable substrate having a forward surface that receives light from the source and a rearward surface opposite the forward surface. The switchable substrate is disposed on the optical path between the source of light and the detecting means. The switchable substrate is disposed on the optical path such that a normal to the forward surface is oriented at a non-zero angle with respect to the optical path.

The switchable substrate includes a plurality of pixels. Each pixel includes at least one means for switching optical states. The switching means is capable of being switched between a first optical state and a second optical state. In the first optical state, a first spectral band of the light is reflected from the switching means toward a viewing system offset from the optical path. In the second optical state, the first spectral band is transmitted through the switching means toward the detecting means. In various implementations, the detecting means includes a photodiode including at least one of: silicon, germanium, and gallium arsenide (GaAs). In various implementations, the switching means includes an electromechanical systems device. Various implementations of the electromechanical systems device can include an optical stack and a movable layer separated from the optical stack by a gap having a height. The movable layer is configured to be moved to change the height of the gap and switch the switchable element between the first state and the second state.

One innovative aspect of the subject matter described in this disclosure includes a method of manufacturing an imaging device. The method comprises providing a sensor configured to detect light in visible and infrared spectral ranges propagating along an optical path from a source of light and disposing a switchable substrate having a forward surface and a rearward surface opposite the forward surface between the source of light and the sensor. The switchable substrate is disposed such that a normal to the forward surface is oriented at a non-zero angle with respect to the optical path. The switchable substrate includes a plurality of individually addressable pixels. Each pixel includes at least one switchable element that is capable of being switched between a first optical state and a second optical state. In the first optical state, a first spectral band of the light is reflected from the switchable element toward a viewing system offset from the optical path, and in the second optical state, the first spectral band is transmitted through the switchable element toward the sensor.

Various implementations of the method of manufacturing include forming the switchable element by: forming an optical stack over a transmissive substrate and forming a movable layer over the optical stack such that the movable layer is separated from the optical stack by a gap having a height. In various implementations, the movable layer includes a transparent conducting oxide.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

Example implementations disclosed herein are illustrated in the accompanying schematic drawings, which are for illustrative purposes only.

FIG. 1 illustrates an implementation of a switchable substrate.

FIG. 2 illustrates an implementation of a switchable element including an electromechanical (EMS) systems device that is switched between a first optical state and a second optical state.

FIG. 3A illustrates the transmissivity of an implementation of a switchable element depicted in FIG. 2 in the first and second optical states.

FIGS. 3B-3E show the transmissivity of the switchable element depicted in FIG. 2 for wavelengths in various spectral regions in the first and second optical states.

FIG. 4A illustrates an implementation of a conventional camera including an aperture, lens elements, a mechanical reflex mirror, a viewing system, a shutter and a sensor.

FIG. 4B illustrates an implementation of a camera including a switchable substrate depicted in FIG. 1 that is configured as a reflex mirror.

FIG. 4C illustrates an implementation of a camera including a switchable substrate depicted in FIG. 1 that is configured as a shutter.

FIG. 4D illustrates an implementation of a camera including a switchable substrate depicted in FIG. 1 that is configured as an aperture.

FIG. 5 is a flow chart illustrating examples of a method of manufacturing an imaging device including an implementation of a switchable substrate configured as a reflex mirror.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. As will be apparent from the following description, the innovative aspects may be implemented in any device that is configured for use in still and motion pictures. The innovative aspects may be implemented in any device including a light sensor that receives light from a source and produces an image of the source. Such a device can be referred herein as an imaging device. More particularly, it is contemplated that the innovative aspects may be implemented in or associated with professional and personal photographic and video cameras. The implementations may be implemented in or associated with a variety of electronic devices such as, but not limited to, mobile telephones, multimedia Internet enabled cellular telephones, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers and/or navigators, cameras, camcorders, game consoles, wrist watches, electronic reading devices (e.g., e-readers), computer monitors, and a variety of electromechanical systems devices. Other uses are also possible. The teachings herein are not intended to be limited to the implementations depicted solely in the Figures, but instead have wide applicability as will be readily apparent to a person having ordinary skill in the art.

The color quality and/or resolution of images obtained by still and video cameras can be enhanced by capturing both visible and infrared spectral content of the scene. Photography and video equipment including two side-by-side sensors that simultaneously capture both the visible and the infrared spectral images can have several disadvantages. For example, the two sensors may be required to have matching footprints and power requirements to obtain high quality images. Additionally, using two sensors can increase the cost and footprint of the photography and video equipment. Another disadvantage may be increased complexity of computation required. Specifically, since the visible and infrared images are captured at slightly different angles, sophisticated computational methods may be required to process the two images such that they appear to be captured from the same perspective.

Photography and video equipment that serially capture visible and infrared spectral images by interchanging a filter that passes visible light and blocks infrared light and a filter that passes infrared light and blocks visible light have the disadvantage that the scene may have changed between the time the visible image is captured and the time the near infrared image is captured and thus may not provide accurate information about the scene at a given time. Another possible disadvantage of this approach is that the infrared filter may cut out or reduce the amount of near infrared light that is allowed through the filter. This may result in a loss of near infrared spectral content from the scene which may be useful in further processing of the obtained images.

Various implementations described herein include an imaging device that includes a substrate integrated with a plurality of switchable elements. Each of the plurality of switchable elements can be switched between at least two optical states within a short time, for example, in less than a few hundred microseconds. In some implementations, in a first optical state, the switchable elements are configured to reflect light in the visible spectral range, while in a second optical state, the switchable elements are configured to transmit light in the visible spectral range. Additionally, in the first optical state, the switchable elements can be configured to transmit light in the infrared spectral range, while in the second optical state, the switchable elements can reflect (or absorb) light in the infrared spectral range. In various implementations described herein, the term “switchable substrate” will be used to refer to the substrate integrated with a plurality of switchable elements.

The imaging device can include the switchable substrate positioned in an optical path between a source of light and a broadband sensor. The broadband sensor is sensitive to light in both the visible and infrared spectral ranges such that the imaging device can capture visible and infrared spectral images of still as well as moving subjects. When the switchable elements are in the first optical state, visible light is reflected from the switchable elements and infrared light is transmitted through the switchable elements toward the broadband sensor. Thus, when the switchable elements are in the first optical state, an infrared image can be captured by the broadband sensor. When the switchable elements are in the second optical state, infrared light is reflected from (or absorbed by) the switchable elements, and visible light is transmitted through the switchable elements to the broadband sensor. Thus, when the switchable elements are in the second optical state, a visible image can be captured by the broadband sensor. The rapid switching between the first optical state and the second optical state permits visible and infrared images to be captured in rapid succession (e.g., before a scene has changed substantially). In various implementations, the switchable elements can include an optical stack disposed over the substrate and a movable layer separated from the optical stack by a gap having a height. The movable layer can be electrostatically actuated to change the height of the gap and switch the switchable elements between the first optical state and the second optical state.

Particular implementations of the imaging devices described in this disclosure may realize one or more of the following potential advantages. The imaging device can include a single broadband sensor that enables acquisition of visible and infrared spectral information of a scene from the same angle or perspective. An imaging device including a single broadband sensor instead of a sensor sensitive to light in the visible spectral range and a sensor sensitive to light in the infrared spectral range can be advantageous in reducing cost, complexity and footprint of the imaging device. Additionally, since the plurality of switchable elements can switch from a first optical state in which infrared light is transmitted to a second optical state in which visible light is transmitted in less than a few hundred microseconds, it is possible to acquire visible and infrared spectral content of a scene sufficiently in real time without exchanging visible and infrared filters.

Implementations of the switchable substrate can be used as an alternative to mechanical reflex mirrors in single lens reflex cameras. Since, the plurality of switchable elements in the substrate can electrically switch between a reflective optical state and a transmissive optical state, the switchable substrate is not required to mechanically move out of the optical path to acquire an image in contrast to the mechanically moving reflex mirrors used in conventional cameras. Accordingly, implementations of the switchable substrate that are configured as reflex mirrors in camera can remain fixed in the optical path and mechanical systems that are used to move the mechanical reflex mirror in and out of the optical path in conventional cameras can be eliminated. This can advantageously reduce the size and/or weight of camera. Additionally, not requiring the reflex mirror to be physically moved in and out of the optical path can reduce wear and tear and accordingly extend the lifetime of the camera. Furthermore, elimination of the mechanical reflex mechanism can also reduce power requirements and consequently increase battery life of the cameras.

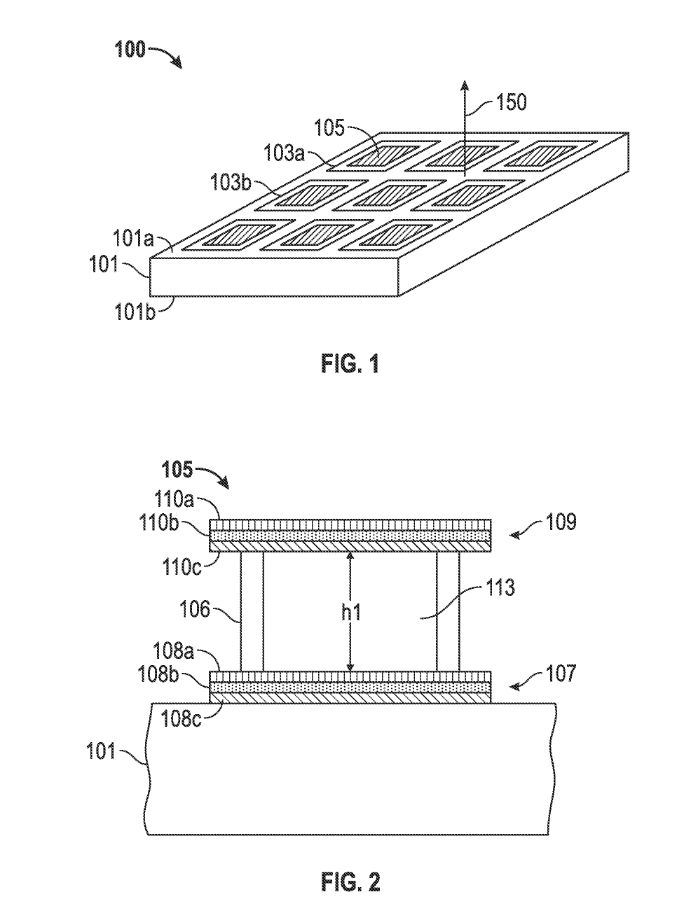

FIG. 1 illustrates an implementation of a switchable substrate 100. The switchable substrate 100 includes a plurality of pixels 103a and 103b disposed on the substrate 101. The substrate 101 includes a material that is at least partially transmissive to light in the visible and near infrared spectral ranges such as glass, plastic, polycarbonate, polyester or cyclo-olefin. The substrate 101 can have a forward surface 101a on which light is incident and a rearward surface 101b opposite the forward surface 101b. A person having ordinary skill in the art will appreciate that the terms “forward” and “rearward” as used in referring to the substrate surfaces herein do not indicate a particular absolute orientation, but instead are used to indicate a surface (“forward surface”) on which light is incident and a surface 101b through which a portion of the light incident on the forward surface 101a can propagate (“rearward surface”). The switchable substrate 100 has a normal 150 perpendicular to the forward surface 101a. In various implementations, the forward and rearward surfaces 101a and 101b of the substrate 101 can be parallel. In other implementations, the substrate 101 can be wedge shaped such that the forward and rearward surfaces 101a and 101b are inclined with respect to each other. The substrate 101 may be formed as a plate, sheet or film, and fabricated from a rigid or a semi-rigid material. In various implementations, portions of the substrate 101 may be formed from a flexible material. The substrate 101 can have a thickness such that it has little impact on the optical properties of the switchable element 105. In various implementations, a thickness of the substrate 101 can be selected depending on the application in which the switchable substrate 100 is used. For example, when the switchable substrate 100 is used as an alternative to mechanical reflex mirrors in camera, the thickness of the substrate 101 can be between approximately 0.1 mm and 0.7 mm. Other substrate thicknesses can be used, for example, greater than approximately 1 or 2 mm.

In various implementations, the plurality of the pixels can be arranged in a plurality of rows and columns. Each of plurality of pixels 103a and 103b can include at least one switchable element 105 that can be switched between a first optical state and a second optical state. In various implementations, the switchable element 105 can be electrically switched between the first and the second optical state by using electrical signals from electronic driver circuits. In various implementations, the switching time in which the switchable element 105 is switched between the first and the second positions can be about 10 ns, 100 ns, 500 ns, 1 μs, 10 μs, 50 μs, 100 μs or 500 μs, etc. In various implementations, switchable elements 105 in each row and column can be driven by a common driver circuit such that all the switchable elements in a row or column are substantially simultaneously switched from the first state to the second state and vice versa. In some implementations, each pixel is individually addressable such that the at least one switchable element 105 in each pixel is individually switched between the first and the second states without reference to switchable elements in other pixels. In some such implementations, each switchable element 105 is individually addressable. A switchable substrate including individually addressable pixels can be spatially patterned, may be advantageous in photography and video equipment in creating apertures with different shapes. In various implementations, in the first optical state the switchable element 105 can be transmissive to light having wavelengths in a first spectral range and in the second optical state the switchable element 105 can absorb or reflect light having the wavelengths in the first spectral range.

In some implementations, the switchable element 105 can include mechanical shutters that can be switched between a transmissive state and an absorptive and/or reflective state. In some implementations, the switchable element 105 can include electro-optic or acousto-optic devices that can be switched between a transmissive state and an absorptive and/or reflective state. In some implementations, the switchable element 105 can include devices that utilize interference or diffraction phenomenon to switch between a transmissive state and an absorptive and/or reflective state. In various implementations, the switchable element can include liquid crystal material that can be switched between a transmissive state and an absorptive and/or reflective state. An implementation of a switchable element 105 including an electromechanical systems device is discussed in further detail below.

FIG. 2 illustrates an implementation of a switchable element 100 including an electromechanical (EMS) systems device that can be switched between a first optical state and a second optical state. The EMS device has a fixed optical stack 107 disposed on the forward surface 101a or the rearward surface 101b of the substrate 101 and a movable optical stack 109 disposed over the fixed optical stack 107 by posts 106. The movable optical stack 109 is separated from the fixed optical stack 107 by a gap 113. The gap can have a height less than about 2 microns. In various implementations the height of the gap 113 can be between approximately 10 to 500 nm. In various implementations, the gap 113 can include air, nitrogen or an inert gas such as argon, neon, xenon, etc. In some implementations, the gap 113 can include a dielectric layer.

The fixed optical stack 107 and the movable optical stack 109 can each, include a plurality of layers (for example, layers 108a, 108b, 108c in the fixed optical stack 107 and layers 110a, 110b, and 110c in the movable optical stack 109). In various implementations, the layer 108c can be a conducting layer of the fixed stack 107 and the layer 110a can be a conducting layer of the movable stack 109. In various implementations, the layers 108a, 108b, 110b and 110c can be dielectric layers. In various implementations, the fixed optical stack 107 and the movable optical stack 109 can each include transparent conducting oxides (TCOs), a plurality of alternate high refractive index and low refractive index layers, dielectrics, and metals. In various implementations, the layers 108a, 108b, 108c, 110a, 110b, and 110c can include Titanium Dioxide, Silicon Dioxide, Aluminum Oxide, Tantalum Oxide, Indium Tin Oxide, Zinc Oxide, Fluorinated Tin Oxide, Silver, Aluminum, Silicon Nitride, Silicon Oxynitride, Zirconium Oxide, Chrome Oxide, etc. In various implementations, the layers included in the optical stack 107 and 109 can absorb light in the visible and infrared spectral ranges. In various implementations, the thickness of the various layers 108a-108c and 110a-110c in the optical stacks 107 and 109 can be less than the coherence length of visible and/or near infrared light. For example, in various implementations, the thickness of each of the various layers 108a-108c and 110a-110c can be less than 1 micron. As an example, the thickness of each of the various layers 108a-108c and 110a-110c can be between approximately 10 to 200 nm. The materials and the thickness of the plurality of layers 108a-108c and 110a-110c can be selected such that the fixed optical stack 107 and the movable optical stack 109 can partially reflect and partially transmit light in the visible spectral range (for example, between approximately 450 nm and approximately 750 nm) and the near-infrared spectral range (for example, between approximately 750 nm and approximately 3000 nm).

The movable optical stack 109 can be electrostatically actuated by applying a voltage across the fixed optical stack 107 and the movable optical stack 109. The voltage required to actuate the movable optical stack 109 can be provided from a driver circuit that is connected to the conducting layers (or electrodes) in the fixed stack 107 and the movable stack 109 of the switchable element 105. In various implementations, the voltage required to actuate the movable optical stack 109 can be provided in the form of an amplitude modulated electrical signal, a frequency modulated electrical signal, a time modulated electrical signal or a pulse width modulated electrical signal. With no applied voltage, the movable optical stack 109 is at a first position over the fixed optical stack 107 such that the gap 113 has a height h1. In this configuration the switchable element 105 is in a relaxed or unactuated state. When a voltage is applied across the conducting layer 108c of the fixed optical stack 107 and the conducting layer 110a of the movable optical stack 109, electrostatic forces are generated between the conducting layer 108c of the fixed optical stack 107 and the conducting layer 110a of the movable optical stack 109 that pull the conducting layers of the fixed optical stack 107 and the movable optical stack 109 towards each other. If the applied voltage is high enough, the movable optical stack 109 is deformed and is at a second position that is closer to the fixed optical stack 107 such that the gap 113 has a height h2 less than h1. In this configuration, the switchable element is in a deformed or biased state. The use of dielectric layers 108a, 108b, 110b and 110c in the fixed stack 107 and/or the movable stack 109 can prevent electrical shorting and control the separation distance between fixed stack 107 and the movable stack 109. The switchable element 105 can be designed by selecting materials, thicknesses and other parameters of the fixed optical stack 107 and the movable optical stack 109 such that the transmissivity and the reflectivity of the switchable element 105 for different spectral bands can vary with variation in the position of the movable optical stack 109 due to optical interference. For example, in various implementations, in the unactuated state, the switchable element 105 can transmit light having wavelengths in a first spectral range (for example, in the visible spectral range) and substantially blocking light having wavelengths outside of the first spectral range; while in the biased state wavelengths in a second spectral range (for example, in the infrared spectral range) are transmitted and light having wavelengths outside of the second spectral range is substantially blocked, where the first and second spectral ranges are different. Accordingly, in some implementations, the unactuated state of the switchable element 105 can correspond to the first optical state described herein, and the biased state of the switchable element 105 can correspond to the second optical state. The movable optical stack 109 can be actuated between the first and the second positions in less than about 100 μs. In various implementations, the time in which the movable optical stack 109 is actuated between the first and the second positions can be about 10 ns, 100 ns, 500 ns, 10 μs or 50 μs.

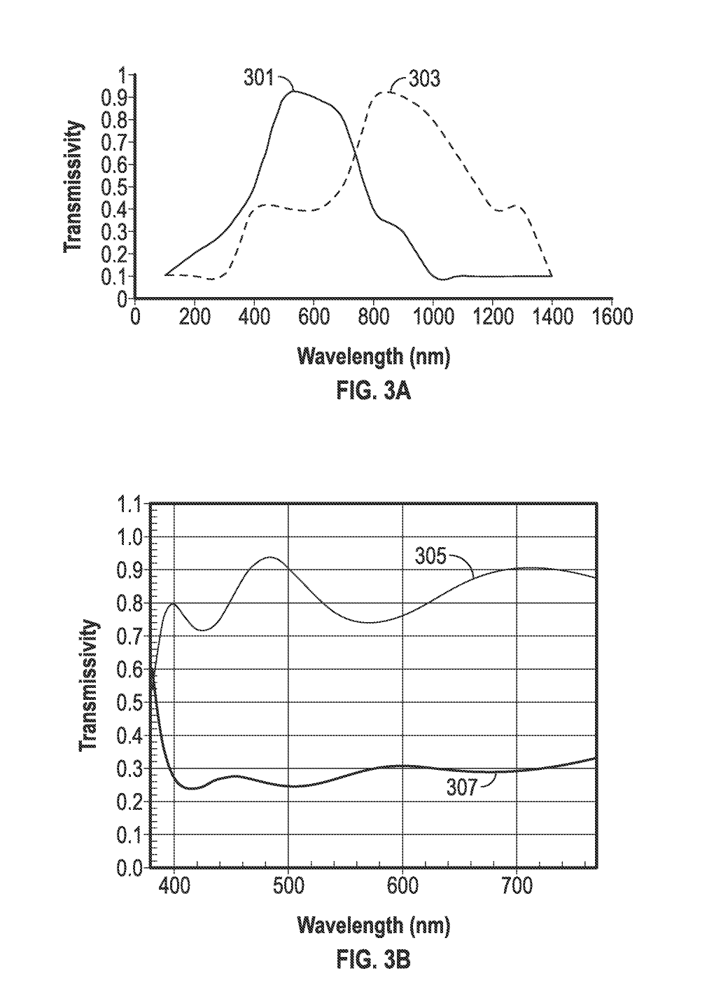

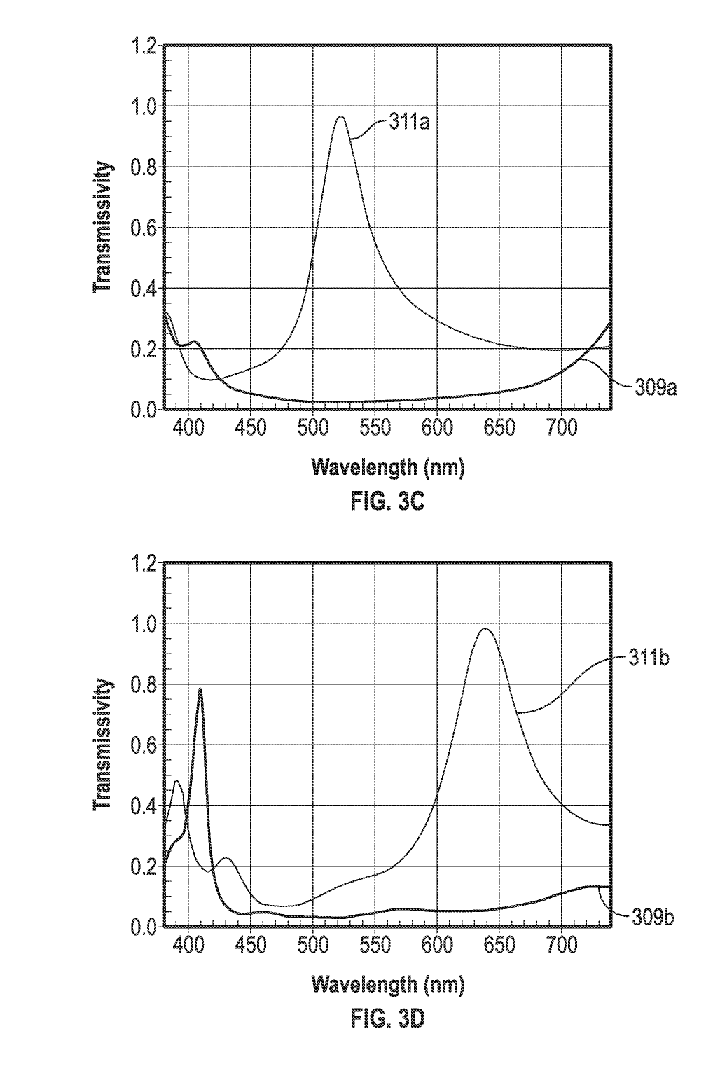

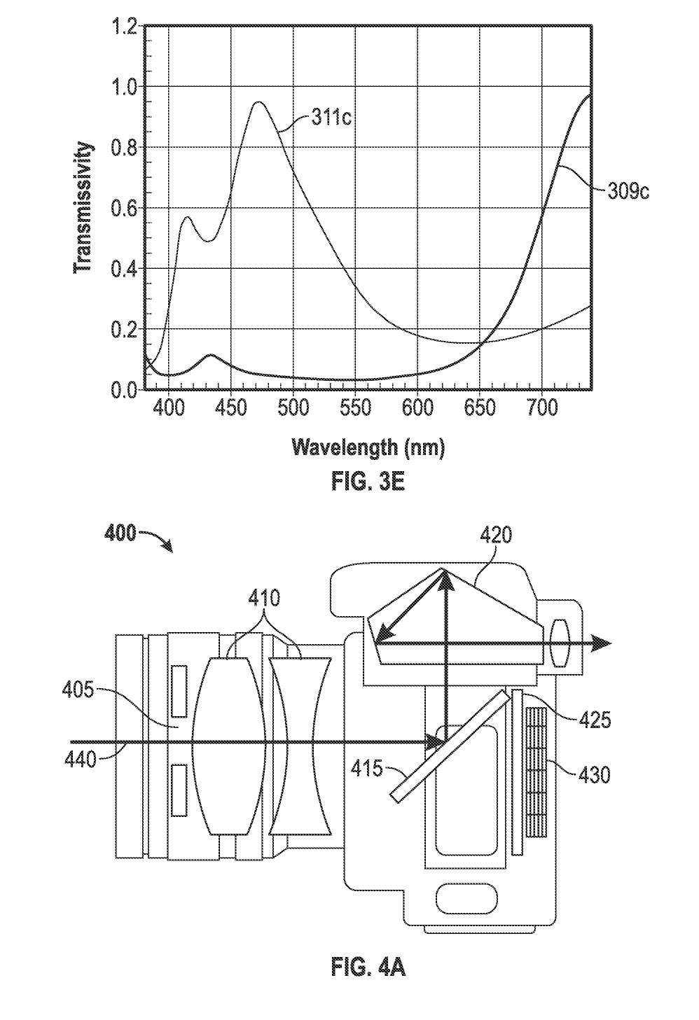

FIG. 3A illustrates the transmissivity of an implementation of a switchable element 105 depicted in FIG. 2 in the first and second optical states. As referred to herein, the transmissivity of the switchable element is the ratio of the amount of light in a spectral band that is transmitted through the switchable element to the amount of light in that spectral band that is incident on the switchable element. Accordingly, if all the light in a spectral band that is incident on the switchable element is transmitted through the switchable element, then the transmissivity is 1. When the movable stack 109 is at the first position, the switchable element 103 transmits light in the visible spectral range as shown by the solid curve 301 and substantially blocks light in the infrared spectral range. Light in the infrared spectral range is blocked by either reflecting the infrared light or by absorbing it in the switchable element 105. When the movable stack 109 is at the second position, the switchable element 105 transmits light in the infrared range as shown by the dashed the curve 303 and at least partially blocks light in the visible spectral range. Light in the visible spectral range is blocked by either reflecting the visible light or by absorbing it in the switchable element 105.

FIGS. 3B-3E show the transmissivity of the switchable element depicted in FIG. 2 in the first and second optical states for wavelengths in various spectral regions. In various implementations, the switchable element 105 can be designed such that in the first optical state visible as well as infrared light is transmitted through the switchable element 105, and in the second optical state only the infrared light is transmitted while the visible light is blocked. In various implementations, the switchable element 105 can be designed such that in the second optical state only the visible light is transmitted while the infrared light is blocked. In various implementations, the switchable element 105 can be designed such that in the first optical state the transmissivity of visible light through the switchable element 105 is relatively high, as shown by curve 305 in FIG. 3B, and in the second optical state the transmissivity of visible light is reduced as shown by curve 307 of FIG. 3B. In some implementations, the switchable element 105 can be designed such that in the second optical state very little light is transmitted through the switchable element 105 (e.g., transmissivities less than about 5%). In some implementations, the switchable element 105 can be designed such that in the first optical state, light in the visible spectral range is substantially blocked while in the second optical state a portion of the visible spectral range that is associated with a certain color (for example, red, green or blue) is transmitted. Accordingly, the switchable element 105 can function as a color filter element. The ability of the switchable element depicted in FIG. 2 to filter colors is depicted in the example transmissivities shown in FIGS. 3C-3E. As discussed above, in various implementations, the transmissivity of the switchable element can be low in the first optical state as indicated by curves 309a, 309b and 309c of FIGS. 3C-3E. In the second optical state, the switchable element 105 can transmit green light (shown by curve 311a of FIG. 3C), blue light (shown by curve 311b of FIG. 3D), or red light (shown by curve 311c of FIG. 3E), depending on the position of the movable stack 109. As referred to herein, reflectivity of the switchable element is the ratio of the amount of light in a spectral band that is reflected by the switchable element to the amount of light in that spectral band that is incident on the switchable element. Accordingly, if all the light in a spectral band that is incident on the switchable element is reflected by the switchable element, then the reflectivity is 1.

In view of the above discussion, the optical characteristics of the switchable element 105 can be generally described in terms of the transmission of light in two different spectral bands (e.g., visible and infrared) and the reflection of light in the two different spectral bands in the first optical state and the second optical state:
(i) In the first state, the switchable element 105 can be considered to have a first transmissivity T1 and a first reflectivity R1 for wavelengths in a first bandwidth and a second transmissivity T2 and a second reflectivity R2 for wavelengths in a second bandwidth; and
(ii) In the second state, the switchable element 105 can be considered to have a third transmissivity T3 and a third reflectivity R3 for wavelengths in the first bandwidth and a fourth transmissivity T4 and a fourth reflectivity R4 for wavelengths in the second bandwidth.

Depending on the desired optical characteristics of the imaging device the switchable element 105 can be designed to achieve various transmissivities T1, T2, T3 and T4 and various reflectivities R1, R2, R3 and R4. Consider an implementation where the first bandwidth corresponds to wavelengths in the visible spectral range and the second bandwidth corresponds to wavelengths in the infrared spectral range and the switchable element 105 is configured to reflect wavelengths in the visible spectral range and transmit wavelengths in the infrared spectral range in the first optical state and reflect wavelengths in the infrared spectral range and transmit wavelengths in the visible spectral range in the second optical state. In such an implementation in the first state, T1<T2 and R1>R2 and in the second state T3>T4 and R3<R4. In various implementations, the reflectivity R1 of the switchable element 105 for wavelengths in the visible spectral range in the first optical can be at least 0.6 or 60%. For example, reflectivity R1 can have a value of 75%, 80% or 90% in the first state. In various implementations, the transmissivity T3 of the switchable element 105 for wavelengths in the visible spectral range in the second optical can be at least 0.6 or 60%. For example, transmissivity T3 can have a value of 75%, 80% or 90% in the second state. In general the value of the transmissivities T1-T4 and reflectivities R1-R4 can be in the range from about 10-90%.

For an implementation of a switchable element 105 that is configured to be broadband transparent (in the visible and infrared) in the first optical state and opaque for all wavelengths in visible and infrared spectral regions in the second optical state T1 is approximately equal to T2, T3<T1 and T4<T2. In such an implementation T1 and T2 can be at least 60% while T3 and T4 can be less than 10%. In such an implementation if all wavelengths in visible and infrared spectral regions are configured to be reflected in the second optical state then R3 and R4 can be at least 60%. For example, R3 and R4 can be between about 60% and about 99%.

Implementations of the switchable element 105 including an EMS device such as those described herein may be fabricated using micro-electromechanical systems (MEMS) manufacturing methods. In one implementation of a method of manufacturing the switchable element 105, the layers of the fixed stack 107 and the movable stack 109 can be formed via sequential deposition of layers using techniques such as, for example, chemical vapor deposition or physical vapor deposition. The gap 113 may be formed via deposition and subsequent removal of a sacrificial layer of a desired thickness, or may be formed by lamination techniques with included support structures to form the gap 113. An etching process can be used to remove the sacrificial layer. The posts 106 can include a dielectric material which is deposited and patterned. Electrical connections between the conducting layers in the fixed stack 107 and the movable stack 109 and any necessary driver or actuation circuitry can be formed at the periphery of the switchable element 105, or at the periphery of the pixels 103a and 103b.

Implementations of the switchable substrate described herein can be used in various applications including but not limited to cameras, facsimile devices, windows, skylights, building integrated photovoltaic products, luminaires, etc. The use of the switchable substrate in a camera is discussed in greater detail below. As discussed above, the implementations of the switchable substrate can enhance the quality of still and moving images. For example, the switchable substrate used with a broadband sensor can be used to capture the spectral content in the visible and infrared spectral range from a scene. The spectral content in visible and infrared spectral range can be processed using computation methods to enhance the color quality, focus, depth of focus, and/or contrast of still and moving images. Additionally, the infrared spectral content can be processed to extract depth information of various objects in a scene which can be useful to create a three-dimensional (3-D) image of the scene. As another example, each pixel in the switchable substrate can be individually addressed to create spatial patterns that selectively allow transmission of light to the sensor. This can be useful in creating spatial patterns in the transmitted and reflected light, in generating apertures which can reduce diffractive effects in captured images, and in spatial filtering of light. As yet another example, the switchable substrate can be temporally modulated such that the transmissivity or reflectivity of each pixel or a group of pixels is varied. This feature can be useful in increasing the dynamic range of the sensor array as discussed in detail below. Implementations of the switchable substrate can replace or enhance the mechanical shutter or the reflex mirror used in conventional cameras as discussed below.

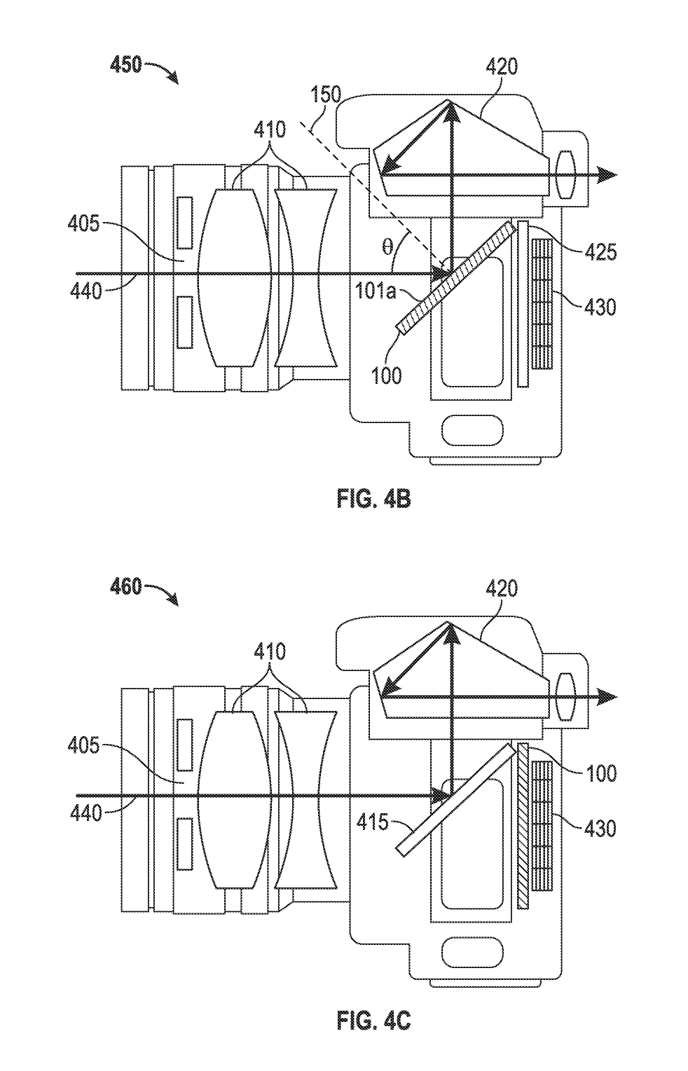

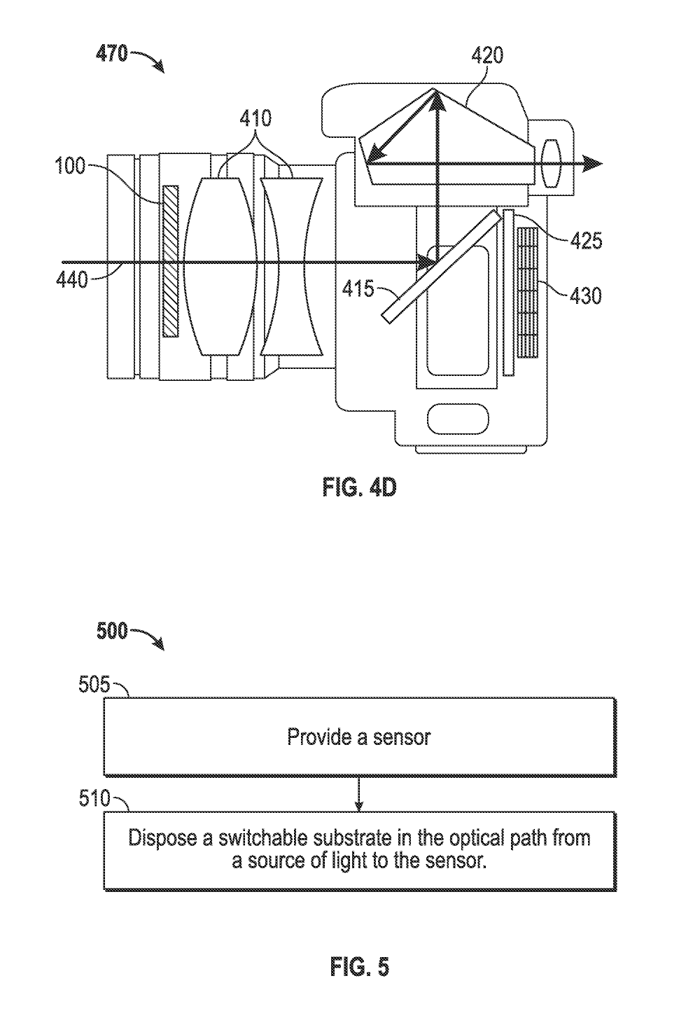

FIG. 4A illustrates an implementation of a conventional camera 400 including an aperture plate having an aperture 405, lens elements 410, a mechanical reflex mirror 415, a viewing system 420, a shutter 425 and a sensor 430. Light from an object or a scene illuminated by a source of light is incident on the lens elements 410 through the aperture 405 and is propagated along an optical path 440 towards the sensor 430. The source of light can include ambient light, which can include light from the surrounding environment such as natural (e.g., sunlight) and/or artificial light. The reflex mirror 415 and shutter 425 are disposed in the optical path 440 between the lens elements 410 and the sensor 430. The viewing system 420 is offset from the optical path 440. The aperture 405 is adjustable to control the amount of light that is directed towards the sensor, for example, by adjusting the focal ratio or “f-number” of the camera. The shutter 425 is configured to expose the sensor 430 to the light from the object during an exposure time. In a conventional SLR or DSLR camera, the reflex mirror 415 is configured to be mechanically moved (or “flipped”) between a first position and a second position. Accordingly, in conventional SLR and DSLR cameras the reflex mirror is also referred to as a “flip-up” mirror. In the first position, as shown in FIG. 4A, the reflex mirror 415 is oriented such that light from the object or the scene to be imaged is directed towards the viewing system 420. In the example shown in FIG. 4A, the viewing system 420 includes optical elements (e.g., a prism and objective lens) that direct light to a viewfinder used by the photographer to view the scene. In other implementations, the viewing system 420 may include a display that outputs an image of the scene. When an exposure is desired, the reflex mirror 415 is moved out of the optical path 440 (e.g., by rotating the mirror to the second position, or by flipping the mirror up to the second position) such that light from the object or scene to be imaged is incident on the sensor 430. Various parts of the camera 400 such as the reflex mirror 415, the shutter 425 and/or the aperture plate can be advantageously replaced by the switchable substrate as further discussed below. In various implementations of the camera 400, the sensor 430 can include one or more broadband photodiodes that can detect wavelengths in both visible and infrared spectral ranges. In various implementations, the photodiode can include at least one of: silicon, germanium and gallium arsenide (GaAs).

### Example Reflex Mirror Implementations

As discussed above, in a conventional camera system, the reflex mirror 415 is a mechanical device that flips between the first and the second state by rotating or moving the mirror. The use of a mechanical reflex mirror 415 can increase the footprint of the camera because a mechanical device is needed to flip the mirror. Moreover, a mechanical reflex mirror 415 can have a reduced life time due to the presence of moving parts. Additionally, a mechanical reflex mirror 415 requires power to flip the mirror, which can reduce battery life.

The mechanical reflex mirror 415 can be replaced with an implementation of the switchable substrate 100 described above. FIG. 4B illustrates an implementation of a camera 450 including a switchable substrate 100 that is configured to replace the mechanical reflex mirror 415 of FIG. 4A. The switchable substrate 100 can include any of the implementations described herein. The switchable substrate 100 can be disposed in the optical path 440 such that the normal 150 to the forward surface 101a of the switchable substrate 100 is oriented at a non-zero angle θ with respect to the optical path 440 as shown in FIG. 4B. In various implementations, the normal to the forward surface 101a is oriented at an angle of about 45 degrees with respect to the optical path 440. In some implementations, the non-zero angle between the normal to the forward surface 101a and the optical path 440 can be about 20 degrees, about 30 degrees, about 60 degrees, about 80 degrees, etc. In other implementations, the non-zero angle θ can be in a range from about 30 degrees to about 60 degrees.

The switchable substrate 100 can be configured such that in the first optical state, the transmission of wavelengths in the visible spectral range is low (for example, about 5-20% of the incident light in the visible spectral range is transmitted) while the reflection of wavelengths in the visible spectral range is high (for example, about 60-95% of the incident light in the visible spectral range is reflected) such that the incident light from the object or the scene to be imaged is reflected from the switchable substrate 100 toward the viewing system 420. In various implementations, the reflectivity of the switchable substrate 100 to wavelengths in the visible spectral range in the first optical state is at least 60%. For example, the reflectivity of the switchable substrate 100 to wavelengths in the visible spectral range in the first optical state can be greater than about 75%, about 80%, about 90%, about 95%, or about 99%. A photographer capturing the object or the scene can compose the shot by viewing the reflected visible light via the viewing system 420. To take an exposure, the photographer can depress a shutter release button which can cause at least some of the switchable elements 105 in the switchable substrate 100 to switch to the second optical state and to expose the sensor such that wavelengths in the visible spectral range are incident on the sensor 430. In the second optical state the transmissivity of the switchable substrate 100 is greater than the reflectivity, so that a large portion of the incident light passes through the switchable substrate 100 to be detected by the sensor 430. In various implementations, the transmissivity of the switchable substrate 100 in the second optical state for wavelengths in the visible spectral range can be at least about 60%. For example, the transmissivity of the switchable substrate 100 to wavelengths in the visible spectral range in the second optical state can be greater than about 75%, 80%, 90%, 95%, or 99%.

Replacing the mechanical reflex mirror 415 with an implementation of the switchable substrate 100 can provide several advantages. For example, since the switchable substrate 100 switches between a reflective state and a transmissive state by electrostatic actuation of EMS devices or some other electro-optic, acousto-optic, diffractive or refractive effect, the switchable substrate can be fixed in the optical path. Accordingly, there is no need to mechanically move the switchable substrate 100 that is configured as a reflex mirror and moving parts can be eliminated. Moreover, since mechanical movement of the switchable substrate 100 that is configured as a reflex mirror is not required, potential space savings can be obtained because a mechanical system for moving the switchable substrate 100 that is configured as a reflex mirror is not needed. Additionally, since the switchable elements 105 can be switched between the reflective and transmissive states at time scales of approximately 100 us or less, fast response can be obtained when the shutter release button is depressed. Additionally, battery life can be enhanced since there is no need to flip the switchable substrate 100 that is configured as a reflex mirror out of the image path.

In some implementations, the camera 450 can be designed to take a visible image and a near-infrared image temporally spaced by a short duration (e.g., 100 μs or less). The visible and near-infrared images can be used for image enhancement using various image enhancement algorithms. In such implementations, in the first optical state when visible light is reflected toward the viewing system 420, infrared light can be passed through the switchable substrate 100 toward the sensor 430. After composing the shot, the photographer can depress the shutter release which will cause the shutter 425 to be opened to obtain an infrared image. The switchable substrate 100 can then be switched to the second optical state, in which visible light is passed while infrared light is absorbed or reflected. The shutter 425 can be opened a second time to obtain the visible image. The two images can then be processed to generate an enhanced image.

In various implementations, the pixels 103a and 103b of the switchable substrate 100 can be spatially modulated to create spatial patterns in the reflected or transmitted light. Additionally, the switchable element 105 of pixels 103a and 103b of the switchable substrate 100 can be temporally modulated by using time modulated signals, frequency modulated signals or pulse width modulated signals for an exposure time to spatially vary the amount of light transmitted through or reflected from the switchable substrate 100. In various implementations, the exposure time can be equal to or be proportional to the duty cycle of the electrical signal that is used to temporally modulate the switchable element 105. The duty cycle of the electrical signal that is used to temporally modulate the switchable element 105 can be between about 10 ns-100 μs. Temporally modulating the switchable element 105 for an exposure time can advantageously increase the dynamic range of the viewing system 420 and/or the sensor 430. To increase dynamic range of the sensor 430 or the viewing system 420, it generally may be desirable that the brightness of the acquired image be spatially uniform. To achieve spatial uniformity in brightness, the switchable substrate 100 can be configured to decrease light in the brightest regions of the image. One method of to decrease light in the brightest regions of the image is to capture an initial image with the pixels of the switchable substrate 100 in their most transparent state. Based on the initial image, regions where the brightness of the image exceeds a threshold (e.g., the maximum detection range of the sensor 430) are identified. The switchable elements 105 of pixels in these “bright” regions can be modulated to be less transmissive during the exposure to decrease the light in the bright regions to be below the threshold. For example, the switchable elements 105 in the bright regions can be temporally modulated between being transmissive and reflective so that the average transmissivity during the exposure is at an appropriate level. The amount of modulation applied to any particular switchable element can depend on how high the brightness of the image is compared to the threshold (e.g., brighter regions of the image are modulated more than less bright regions of the image). By keeping the brightness of the image below threshold, the likelihood of overexposing (or burning out) the sensor 430 can be reduced, and the image of the scene can be captured with higher dynamic range.

### Example Shutter Implementations

The shutter 425 can include the switchable substrate 100 described herein. In various implementations, a conventional mechanical shutter 425 can be replaced or used in conjunction with the switchable substrate. FIG. 4C illustrates an implementation of a camera 460 including a switchable substrate 100 depicted in FIG. 1 that is configured as a shutter. In the illustrated implementation, the switchable substrate 100 is disposed in front of the sensor 430. The switchable substrate 100 is configured to be transmissive to light from a source in the visible and/or infrared spectral range in the first state and opaque to light from the source in the visible and/or infrared spectral range in the second state. Thus, the switchable substrate 100 can be electronically switched to a transmissive state during the exposure time of the image to expose the sensor 430 to light during the exposure. The switchable substrate 100 can be in an opaque state before and after the exposure. Replacing the conventional shutter or providing the conventional shutter with an implementation of the switchable substrate 100 can provide several advantages. For example, the switchable substrate 100 can be used to improve dynamic range of the sensor by modulating the transmissivity of switchable elements in “bright” regions of the image in a way similar to the way described above.

### Example Aperture Implementations

The conventional aperture plate 405 in a camera can be replaced with an implementation of the switchable substrate 100 described above. FIG. 4D illustrates an implementation of a camera 470 including a switchable substrate 100 that is configured as an aperture plate. The switchable substrate 100 functions as an aperture by configuring a first set of the plurality of switching elements 105 of the switchable substrate 100 to be in the first optical state such that light from the source is transmitted to sensor 430 through the first set of switchable elements 105. A second set of the plurality of switching elements 105 are configured to be in the second optical state to block light from the source. In this manner, the amount and spatial pattern of light transmitted to the sensor can be controlled. The number and arrangement of the first set of switchable elements can be adjusted to achieve a desired aperture stop, e.g., a square, circular or elliptical aperture of a desired size (e.g., to achieve a desired focal ratio). Additionally, the switchable substrate 100 can be configured as an iris to achieve a standard aperture function or to achieve computational multi-aperture imaging in various computational camera implementations. In various implementations, the switchable substrate 100 can be configured to create apertures with a fixed or a variable dimension (for example, a diameter for a circular aperture, a length for a rectangular aperture, etc.) having a value between about 30 μm-1 mm.

FIG. 5 is a flow chart illustrating an example of a method of manufacturing an imaging device including an implementation of a switchable substrate 100. At block 505, a sensor, such as a broadband sensor is provided. The broadband sensor can be configured to detect light in the visible and infrared spectral ranges. The sensor can include one or more photodiodes including silicon, germanium or GaAs. At block 510, a switchable substrate is disposed along an optical path between a source of light and the sensor. The switchable substrate can be similar to the implementations of the switchable substrate 100 disclosed herein. The switchable substrate can have a forward surface and a rearward surface opposite the forward surface in the optical path such that the normal to the forward surface of the switchable substrate is oriented at a non-zero angle with respect to the optical path. In various implementations, the non-zero angle can be about 45 degrees.

The implementations described herein can further include filters to reduce the amount of ultraviolet (UV) or infrared (IR) radiation that is transmitted through. Additionally, the implementations described herein can include anti-reflections coatings, diffusers, or other optical components that can enhance the quality of the images.

A wide variety of other variations are also possible. Films, layers, components, and/or elements may be added, removed, or rearranged. Additionally, processing operations may be added, removed, or reordered. Also, although the terms film and layer have been used herein, such terms as used herein include film stacks and multilayers. Such film stacks and multilayers may be adhered to other structures using adhesive or may be formed on other structures using deposition or in other manners.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An imaging device comprising:
a sensor configured to detect light in visible and infrared spectral ranges propagating along an optical path from a light source; and
a switchable substrate having a forward surface that receives light from the source and a rearward surface opposite the forward surface, the switchable substrate disposed on the optical path between the source of light and the sensor, the switchable substrate including a plurality of pixels, each pixel including at least one switchable element that is capable of being switched between a first optical state and a second optical state,
wherein the switchable substrate is disposed on the optical path such that a normal to the forward surface is oriented at a non-zero angle with respect to the optical path, and such that
when in the first optical state, a first spectral band of the light is reflected from the switchable element toward a viewing system offset from the optical path, and
when in the second optical state, the first spectral band is transmitted through the switchable element toward the sensor.

2. The device of claim 1, wherein the non-zero angle is about 45 degrees.

3. The device of claim 1, wherein the first spectral band includes wavelengths in a range between approximately 380 nm and 750 nm.

4. The device of claim 1, wherein when the switchable element is in the first state, a second spectral band of the light is transmitted through the switchable element toward the sensor.

5. The device of claim 4, wherein the second spectral band includes wavelengths in a range between approximately 750 nm and 3000 nm.

6. The device of claim 4, wherein the second spectral band includes a portion of the near infrared spectrum.

7. The device of claim 1, wherein the first spectral band includes a portion of the visible spectrum.

8. The device of claim 1, wherein in the first optical state, the first spectral band is reflected with a reflectivity between approximately 60% and approximately 99%.

9. The device of claim 1, wherein in the second optical state, the first spectral band is transmitted with a transmissivity between approximately 60% and approximately 99%.

10. The device of claim 1, wherein the switchable element includes:
an optical stack; and
a movable layer separated from the optical stack by a gap having a height,
wherein the movable layer is configured to be moved to change the height of the gap to switch the switchable element between the first state and the second state.

11. The device of claim 10, wherein the optical stack includes a transparent conducting oxide.

12. The device of claim 10, wherein the movable layer includes a transparent conducting oxide.

13. The device of claim 1, wherein the switchable element can be switched between the first state and the second state in less than about 100 microseconds.

14. The device of claim 1, wherein the sensor includes a photodiode including at least one of: silicon, germanium and gallium arsenide (GaAs).

15. The device of claim 1, wherein each pixel is individually addressable to create spatial patterns in the reflected or transmitted light.

16. The device of claim 15, wherein the at least one switchable element included in each pixel can be temporally modulated for an exposure time.

17. The device of claim 16, wherein the at least one switchable element included in each pixel can be temporally modulated by using at least one of: time modulated signal, frequency modulated signal and pulse width modulated signal.

18. The device of claim 1, configured as a camera.

19. The device of claim 1, wherein the viewing system includes a display.

20. An imaging device comprising:
means for detecting light in visible and infrared spectral ranges propagating along an optical path from a source of light; and
a switchable substrate having a forward surface that receives light from the source and a rearward surface opposite the forward surface, the switchable substrate disposed on the optical path between the source of light and the detecting means, the switchable substrate including a plurality of pixels, each pixel including at least one means for switching optical states, the switching means capable of being switched between a first optical state and a second optical state,
wherein the switchable substrate is disposed on the optical path such that a normal to the forward surface is oriented at a non-zero angle with respect to the optical path, and such that
when in the first optical state, a first spectral band of the light is reflected from the switching means toward a viewing system offset from the optical path, and
when in the second optical state, the first spectral band is transmitted through the switching means toward the detecting means.

21. The device of claim 20, wherein the detecting means includes a photodiode including at least one of: silicon, germanium, and gallium arsenide (GaAs).

22. The device of claim 20, wherein the switching means includes an electromechanical systems device.

23. The device of claim 22, wherein the electromechanical systems device includes:
an optical stack; and
a movable layer separated from the optical stack by a gap having a height,
wherein the movable layer is moved to change the height of the gap and switch the switchable element between the first state and the second state.

24. A method of manufacturing an imaging device, the method comprising:
providing a sensor configured to detect light in visible and infrared spectral ranges propagating along an optical path from a source of light; and
disposing a switchable substrate having a forward surface and a rearward surface opposite the forward surface between the source of light and the sensor such that a normal to the forward surface is oriented at a non-zero angle with respect to the optical path, the switchable substrate including a plurality of individually addressable pixels, each pixel including at least one switchable element that is capable of being switched between a first optical state and a second optical state such that
when in the first optical state, a first spectral band of the light is reflected from the switchable element toward a viewing system offset from the optical path, and
when in the second optical state, the first spectral band is transmitted through the switchable element toward the sensor.

25. The method of claim 24, wherein the switchable element is formed by:
forming an optical stack over a transmissive substrate; and
forming a movable layer over the optical stack such that the movable layer is separated from the optical stack by a gap having a height.

26. The method of claim 25, wherein the movable layer includes a transparent conducting oxide.
